(19) United States
(12) Patent Application Publication
(10) Pub. No.: US 2014/0338718 A1
(43) Pub. Date: Nov. 20, 2014

(54) LOW SHADING LOSS SOLAR MODULE

(71) Applicant: Crystal Solar, Inc., Santa Clara, CA (US)

(72) Inventor: Tirunelveli S. Ravi, Saratoga, CA (US)

(73) Assignee: Crystal Solar, Inc., Santa Clara, CA (US)

(21) Appl. No.: 14/207,149

(22) Filed: Mar. 12, 2014

Related U.S. Application Data
(60) Provisional application No. 61/777,891, filed on Mar. 12, 2013.
(60) Provisional application No. 61/961,233, filed on Oct. 7, 2013.

(51) Int. Cl. H01L 31/02; H01L 31/18

(52) U.S. Cl. CPC H01L 31/0201; H01L 31/1804
USPC 136/244; 438/64

(57) ABSTRACT

A solar cell comprises an optically transparent handle, wherein the handle includes grooves into which tabs are inserted, enabling the use of high aspect ratio tabs with minimal shading of the front side of the solar cell. Electrical connection of the tabs to busbars on the surface of the layers of the solar cell is through apertures at the bottom of each groove on the handle—the grooves being aligned to the busbars. The apertures may be filled with solder, metal pins, metal spheres, etc, and in embodiments the tabs may be metal wires. The solar cells with optically transparent handles may be formed into solar cell modules. Furthermore, in embodiments the handle with integral tabs simplifies and reduces the cost of solar cell and module fabrication since the top surface of the transparent handle including tabs may be completely flat.

### CROSS-REFERENCE TO RELATED APPLICATIONS

This application claims the benefit of U.S. Provisional Application No. 61/777,891 filed Mar. 12, 2013, and U.S. Provisional Application No. 61/961,233 filed Oct. 7, 2013, both incorporated herein by reference in their entirety.

### FIELD OF THE INVENTION

The present invention relates generally to silicon solar cell modules, and more particularly to solar modules with front side glass and tabs configured for low shading loss,

### BACKGROUND

Thin silicon using epitaxy and lift-off is very attractive as a next generation technology since it represents a polysilicon-less, ingot-less and kerf-less approach to making mono-crystalline solar cells. The challenge with this approach has been to process these thin silicon substrates (less than 50 microns thick) with high yield and yet preserve the ability to make high efficiency cells, such as cells with selective emitter formation on the front side and point contacts (as in PERC and PERL cells) on the back side. To fabricate these cells at high yield, the thin silicon must always be attached to a handle during these process steps.

An approach developed by Crystal Solar Corporation (see U.S. patent application publication no. 2013/0056044 and PCT International Publication No. WO 2013/020111 to K. V. Ravi et al.) enables thin epitaxial silicon to remain attached to the silicon substrate on which the epitaxial layer was grown while the high temperature steps of cell making are completed, up to and including screen printing front contacts. The epitaxial layer is then attached to a hard transparent handle (such as a glass sheet), with tabs extending beyond the epitaxial layer and handle, and the epitaxial layer is exfoliated from the substrate. The back side of the cell is completed with aluminum contacts, while the thin silicon is attached to the glass handle. However, such an approach requires tabbing of the thin epitaxial cells before attaching the cells to the handle; this step can be potentially yield limiting since the tabs are typically 200 microns thick and tend to stress the epitaxial layer which is typically only 50 microns thick. Furthermore, the presence of tabs, sticking out beyond the silicon and glass, during the back side processing makes the final backside cell and module processing difficult to automate.

A typical busbar in a standard high efficiency cell is 1.5 mm wide and a typical front to back 156 mm square cell has three busbars. The reason these busbars are 1.5 mm wide is to match the width of the tabs that go on the top of the busbars to connect to the next cell. These tabs are only about 200 microns thick and a 1.5 mm tab is needed to carry the current from the cell (typically 3 amperes per busbar). Tabs are soldered on to the busbars and the tabs are later strung together, front to back, connecting adjacent cells in a module to form a series string of cells. The width of the tabs results in shading losses—the tabs covering areas of the solar cells which consequently do not receive light and thus do not contribute to power generation. Approaches to eliminate the shading losses completely such as interdigitated back contact (IBC) cells or metal wrap through (MWT) cells do exist but all of them involve significantly increasing the complexity of cell processing. For example, in the case of IBC, electrically isolated contacts have to be made on the back side of the cell by masking part of the cell. In the case of MWT, holes have to be drilled through the cell to bring all of the current carrying busbars to the back of the cell. The busbar area is significantly reduced, but complications arise when the tabs of the two contacts have to be electrically isolated from each other. All of this is even more complicated when it comes to thin silicon cells, which are mechanically fragile; for example, drilling holes in thin silicon may easily lead to micro-cracking.

There is a need for improved tab configurations for solar cells, and for improved fabrication processes, particularly for thin silicon solar cells.

### SUMMARY OF THE INVENTION

The present invention provides a solar cell with a transparent handle, wherein the handle includes grooves/slots into which tabs are inserted, enabling the use of high aspect ratio tabs which reduce the shading of the front side of the solar cell when compared to conventional low aspect ratio tabs. Electrical connection of the tabs to busbars on the surface of the solar cell is through apertures at the bottom of each groove on the transparent handle—the grooves being aligned to the busbars. The apertures may be filled with solder, metal pins, metal spheres or other electrically conductive materials. Furthermore, in embodiments the tabs may be metal wires such as copper wires. The solar cells with transparent handles may be formed into solar cell modules, wherein the solar cells are strung together in series—the tabs connecting the front of one solar cell to the back of the next—and the series connected solar cells are laminated between front and back sheets. Furthermore, the transparent handle with integral tabs simplifies and reduces the cost of solar cell and module fabrication since the top surface of the transparent handle including tabs is completely flat.

According to aspects of the present invention a solar cell structure may comprise: solar cell layers with busbars on the surface of the solar cell layers; a first layer of bonding material over the surface of the solar cell layers and over the surface of the busbars on the surface of the solar cell layers; an optically transparent handle with grooves for tabs and apertures at the bottom of the grooves, wherein the grooves in the optically transparent handle are aligned with the busbars of the first structure and the apertures in the optically transparent handle are aligned with the openings in the first layer of bonding material, wherein the first layer of bonding material attaches the optically transparent handle to the solar cell layers, and wherein the first layer of bonding material has openings to match the apertures in the optically transparent handle; electrical contact materials in the apertures in the optically transparent handle, the electrical contact materials making electrical contact between corresponding electrical contact materials and busbars; and tabs in the grooves, the tabs making electrical contact between corresponding electrical contact materials and tabs.

According to further aspects of the present invention, a method of fabricating a solar cell may comprise: providing a structure including solar cell layers with busbars on the surface of the solar cell layers; providing an optically transparent handle with grooves for tabs and apertures at the bottom of the grooves; applying a sheet of bonding material over the surface of the solar cell layers and over the surface of the busbars on the surface of the solar cell layers, wherein the sheet has openings to match the apertures in the optically transparent handle; aligning the grooves in the optically transparent handle with the busbars of the structure and the apertures in the optically transparent handle with the openings in the sheet, and laminating the optically transparent handle to the structure; introducing electrical contact materials into the apertures in the optically transparent handle, and making electrical contact between corresponding electrical contact materials and busbars; and inserting tabs into the grooves and making electrical contact between corresponding electrical contact materials and tabs.

Further aspects of the invention include solar cell modules comprising the solar cells described herein, and methods for forming the solar cell modules from the solar cells described herein.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1A is a top view representation of three solar cells in a module, according to some embodiments of the present invention;

FIG. 1B is a cross sectional representation of the module of FIG. 1A;

FIG. 2 is a top view representation of a tab, according to some embodiments of the present invention;

FIG. 3 is a perspective view representation of a sheet of front side glass for a solar cell, according to some embodiments of the present invention;

FIGS. 4-6 are representations of a first series of process steps for the fabrication of a solar cell, according to some embodiments of the present invention;

FIGS. 7-11 are representations of a second series of process steps for the fabrication of a solar cell, according to some embodiments of the present invention;

FIG. 12 shows a cross-sectional representation of a concave light-reflective tab, according to some embodiments of the present invention; and

FIG. 13 is a photograph of the front side of a solar cell fabricated according to the second process flow of the present invention.

### DETAILED DESCRIPTION

Embodiments of the present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

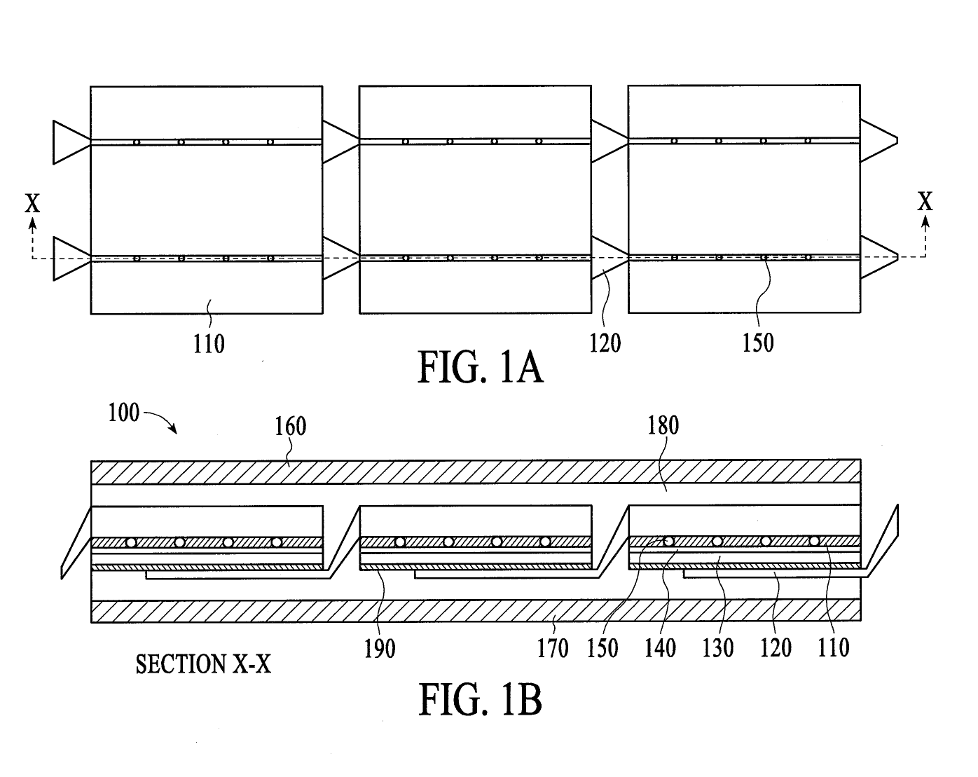

FIGS. 1A & 1B show a top view and a cross-sectional view of an example of a solar cell module according to some embodiments of the present invention. The solar cell module 100 mat comprise: top and bottom sheets 160 and 170, respectively; and encapsulant/bonding material 180 bonding the top and bottom sheets to a string of solar cells. Each solar cell may comprise: an optically transparent handle 110 attached to epitaxial silicon solar cell layers 130; busbars 140 on the top surface of the solar cell layers 130; and solder contacts 150 electrically connecting the busbars to corresponding tabs 120. Backside metallization layers 190 provide for electrically connecting to the tabs 120 on the backside. In FIG. 1A, the position of the solder contacts 150, which are actually below the tabs, are indicated even though they would not be visible in a top view.

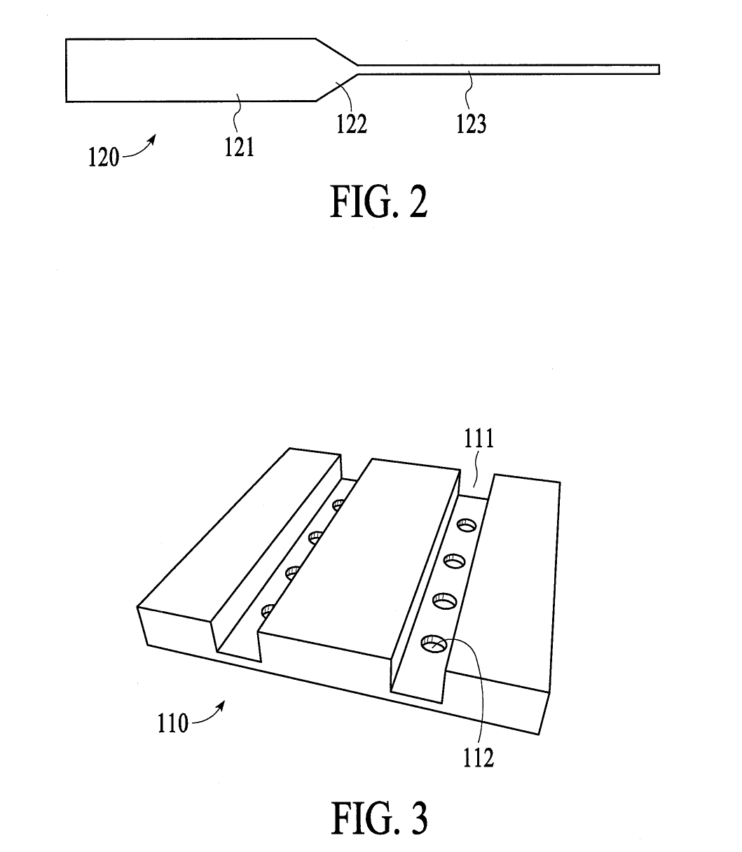

FIG. 2 shows a top view of a tab 120, according to some embodiments of the present invention. Referring to FIGS. 1A, 1B & 2, the tab 120 is shown to comprise a thin and wide portion 121, a transition portion 122 and a tall and thin portion 123. The portion 121 is used to electrically connect to the back of a solar cell (the wide surface making contact to the back of the solar cell) and the portion 123 fits in the slots/grooves provided in the transparent handle (see FIG. 3) and makes electrical contact to the busbars, as described above. The portion 122 connects the portions 121 and 123, transitioning from the back to the front surface of consecutive serially connected solar cells. The tabs may be made of OFHC copper with a tin or solder coating, for example, FIG. 2 is not drawn to scale; the length of the different portions of the tab will be sized to match the solar cell substrates being used. Furthermore, the length of the portion 123 will be sized to match the length of the slots/grooves in the optically transparent handle, and the dimensions of the tab measured perpendicular to its length—height and width—may be determined as described below.

FIG. 3 shows a perspective view of a transparent handle 110, according to some embodiments of the present invention. The handle 110 has grooves/slots 111 in the top surface and apertures 112 along the length of each groove/slot, for allowing electrical connections to be made between the tabs 120 and corresponding busbars 140. The handles may be made of glass, acrylic or other optically transparent polymer materials with the requisite properties, including rigidity or flexibility, depending on the application. The apertures 112 in the transparent handle 110 may be formed by laser drilling—using a green laser, for example. The slots/grooves 111 may also be formed by laser ablation, although preformed slots/grooves may be readily introduced during the production of the glass or acrylic sheet. Note that the depth of the grooves/slots is preferably matched to the height of the portion 123 of the tabs 120. Furthermore, the width of the grooves/slots is preferably slightly wider than the width of the tabs, permitting ease of placement of the tabs, with sufficient room for the encapsulant to flow between the tab and the transparent handle—for example, a slot width 0.1 mm more than the tab width. An example of dimensions of the features of a 156×156 mm² transparent handle for a 0.3 mm wide×1.1 mm tall tab is as follows: 1.6 mm thick handle with slots/grooves 0.4 mm wide and 1.1 mm tall and apertures 0.5 mm tall and approx. 0.2 mm in diameter. However, a wide range of tab sizes can be accommodated according to the present invention, ranging from a high aspect ratio tab, such as in the preceding example, to a more conventional 1.5 mm wide×0.2 mm tall tab, for example. In embodiments the ratio of groove height to groove width may be at least 1.0:1.0, in further embodiments the ratio may be at least 2.0:1.0, and in other embodiments the ratio may be at least 2.7:1.0; the corresponding ratios of tab height to tab width for the thin portion 123, may in embodiments be greater than 1.0:1.0, in further embodiments the ratio may be greater than 2.0:1.0, and in other embodiments the ratio may be greater than 2.7:1.0, respectively. Furthermore, the height of the apertures may be determined in some embodiments by the thickness of optically transparent handle that must remain below the grooves/slots in order to provide mechanical integrity of the handle to reduce the occurrence of mechanical failures during handling to an acceptable level. For example, in embodiments the ratio of aperture 112 height to groove/slot 111 height may be at least 1.0:4:00, in further embodiments the ratio may be at least 1.0:2.0, and in other embodiments the ratio may be at least 1.0:1.0.

The reason the busbar in a typical prior art solar cell is 1.5 mm wide has to do with the current carrying capacity of the tabs, where a typical tab's cross-section is 1.5 mm×0.2 mm=0.3 mm². This same cross section can be achieved by having a significantly narrower tab and compensating for the loss in width by an increase in height. This is now possible in the present invention since in embodiments the glass may be at least 1 mm thick. Thus, slots in the glass can be made that are 0.4 mm wide by 0.8 mm deep, for example, that will hold the tabs in place while significantly reducing the front shading loss. (The typical area covered by a prior art busbars in a 156×156 mm² cell is 0.15 cm×15.6 cm×3=7.02 cm². Whereas the area covered by a 0.4 mm wide busbar of the present invention may be 0.04×15.6×3=1.87 cm², for example. For this example there is a 75% reduction in the area shaded by the busbar without the complexities of modifying the cell or the module design.)

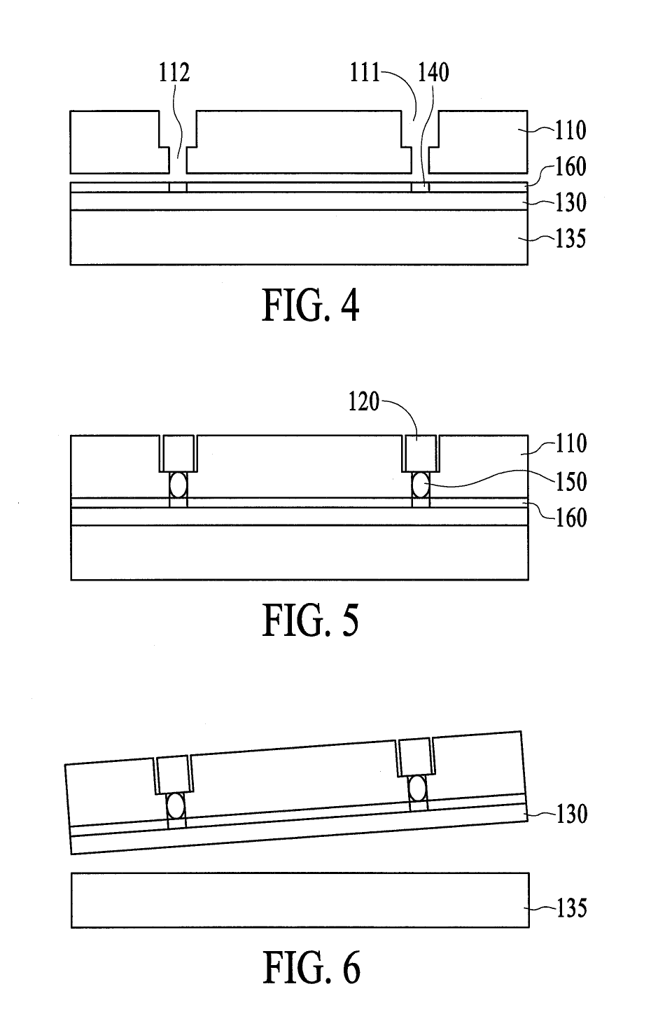

An example of a first process flow for fabrication of a solar cell according to some embodiments of the present invention is shown in the cross-sectional representations of FIGS. 4-6 (the cross-sectional plane for FIGS. 4-6 being perpendicular to the sectional plane X-X of FIG. 1, although FIGS. 4-6 represent the fabrication of a single solar cell rather than illustrating a finished module). In FIG. 4 an optically transparent handle 110 is shown being aligned to a solar cell such that the apertures 112 and grooves/slots 111 are aligned to the busbars 140, which run into the plane of the page. A very thin layer of encapsulant/bonding material 160 is used to bond the handle to the surface of the solar cell. The encapsulant layer 160 is applied such that the busbars are not covered where the apertures 112 in the handle 110 will be located by having pre-cut holes in the encapsulant layer (which can be made by simple punching) in such a way that the holes don't close after the first lamination so that the busbar is accessible through the holes in the transparent handle for making electrical contact. In FIG. 5, solder contacts 150 are introduced into the apertures 112 in the transparent handle 110. The tabs 120 are then introduced into the grooves/slots 111 and electrically connected to corresponding busbars 140 by the solder contacts 150. In FIG. 6, the solar cell is separated from the silicon substrate 135, using techniques described in U.S. Patent Application Publication No. 2013/0056044 and PCT International Publication No. WO 2013/020111 to K. V. Ravi et al. Once the solar cell is separated from the silicon substrate, the backside of the solar cell can be processed—including deposition of a backside metallization layer 190 (see FIG. 1B).

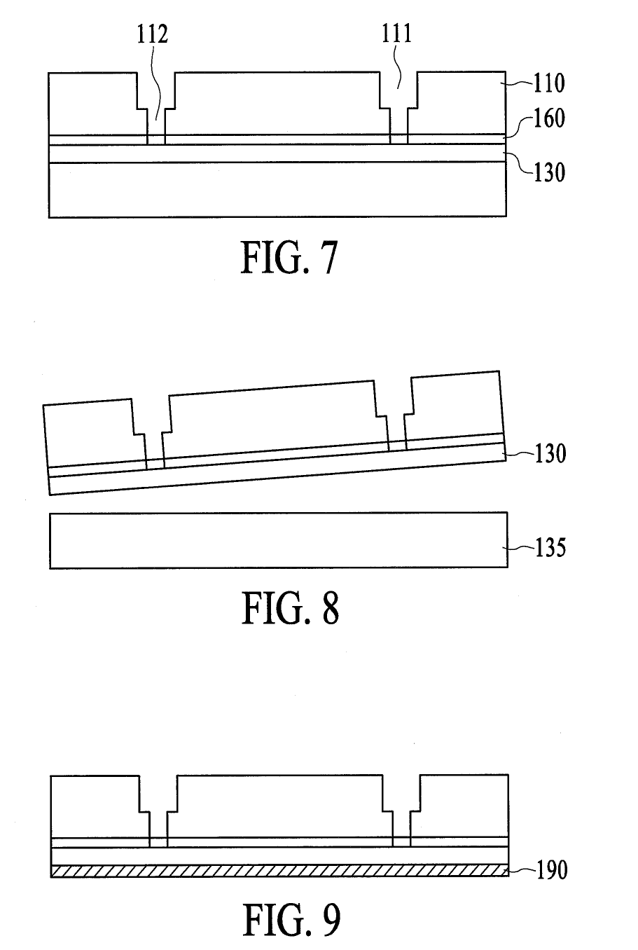

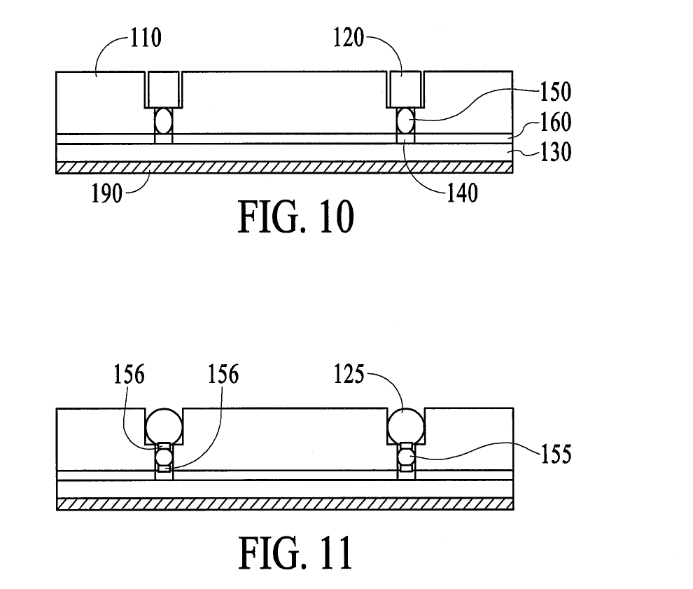

An example of a second process flow for fabrication of a solar cell according to some embodiments of the present invention is shown in the cross-sectional representations of FIGS. 7-11 (with the same cross-sectional plane as for FIGS. 4-6). In FIG. 7 an optically transparent handle 110 is shown affixed to a solar cell such that the apertures 112 and grooves/slots 111 are aligned to the busbars 140, which run into the plane of the page. A very thin layer of encapsulant/bonding material 160 is used to bond the handle to the surface of the solar cell. The encapsulant layer 160 is applied such that the busbars are not covered where the apertures 112 in the handle 110 are located by having pre-cut holes in the encapsulant layer (which can be made by simple punching) in such a way that the holes don't close after the first lamination so that the busbar is accessible through the holes in the transparent handle for making electrical contact. In FIG. 8, the solar cell is separated from the silicon substrate 135, using techniques described in U.S. Patent Application Publication No. 2013/0056044 and PCT International Publication No. WO 2013/020111 to K. V. Ravi et al. Once the solar cell is separated from the silicon substrate, the backside of the solar cell can be processed normally without the complications of pre-tabbing—depositing a backside metallization layer 190, as shown in FIG. 9. Note that backside processing—using PVD (physical vapor deposition) or LFOC (laser-fired ohmic contacts), for example—was found to be easier at this stage before tabs are affixed. In FIG. 10, solder contacts 150 are introduced into the apertures 112 in the transparent handle 110. The tabs 120 are then introduced into the grooves/slots 111 and electrically connected to corresponding busbars 140 by the solder contacts 150.

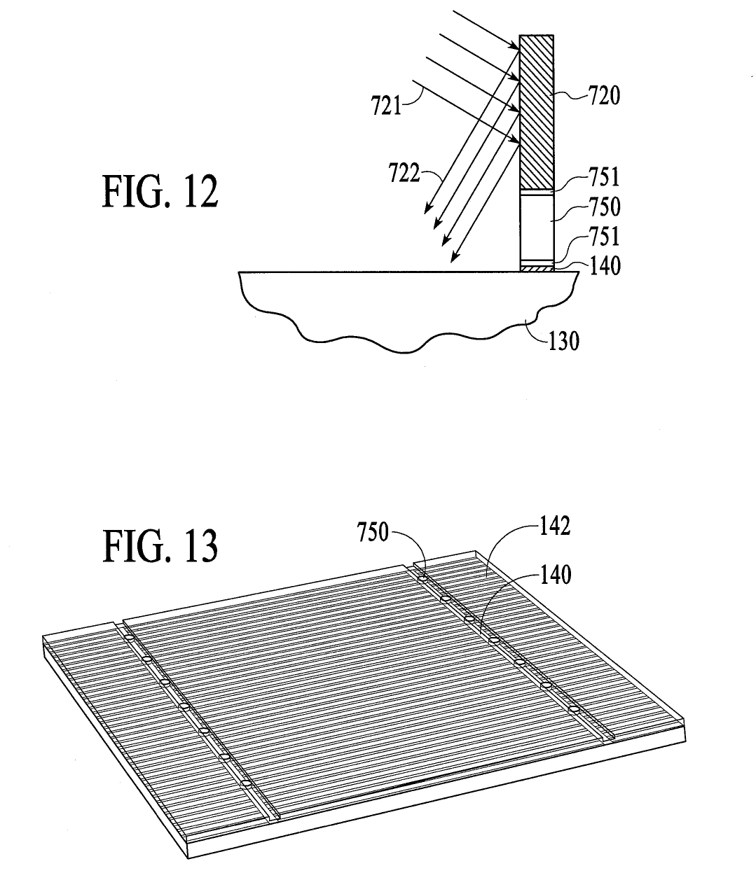

Furthermore, in embodiments, instead of filling the apertures 112 in the transparent handle 110 with solder, pre-tinned copper studs, pre-tinned copper spheres or other electrically conductive materials can be used—fixed in place with a material such as conductive adhesive, conductive silver paste, solder, etc. Note that the studs and spheres may be pre-tinned for better wetting by solder during the tab soldering step. See FIG. 11 for an example of the pre-tinned copper spheres 155 and see FIG. 12 for an example of the studs 750. It is noted that the pre-tinned copper spheres are expected to present a lower cost manufacturing process than either using solder or pre-tinned studs; furthermore, the copper spheres can easily be dispensed into the apertures in the transparent handle using a simple pick and place mechanism or similar. Pre-tinning may be achieved using an electroless deposition of Sn on the copper spheres and studs.

Yet furthermore, since solder will be contacting both the busbar and the tab, the tab can also be an electrically conductive wire, such as a copper wire, with an appropriate diameter which can be dropped into the grooves as shown in FIG. 11—see copper wire 125 contacting the surface of the pre-tinned copper sphere 155 with solder 156 in between. As shown in FIG. 11, the solder on the surface of the pre-tinned copper sphere 155 will effectively wet the place where the sphere and the wire touch providing a good contact, and the same is true for the place where the sphere touches the busbar. The copper wire may also be used with the solder filled apertures and with the pre-tinned studs. The solder 156 may be deposited on the busbars at the bottom of the apertures prior to dropping the spheres into the apertures and then solder may be deposited on top of the spheres prior to dropping the tab into the groove.

A photograph of the front side of a solar cell fabricated using the second process flow and copper studs is provided in FIG. 13. The handle on the front side of the solar cell is transparent; consequently, the front side metallization is seen through the handle. Two busbars 140 are seen running horizontally across the solar cell; the parallel lines which run vertically are current collection fingers 142 which channel current to the busbars. The current collection fingers may be fabricated on the surface of the silicon solar cell layers at the same time as the busbars. Circular features 750 can be observed in FIG. 13 which are copper studs which are positioned in the apertures in the transparent handle see FIG. 12 and associated description provided below. Tabs have not yet been added to the solar cell in FIG. 13. The solar cell in FIG. 13 may be characterized (I-V under illumination) using the copper studs to make electrical contact to the front side busbars and metallization on the backside for making electrical contact to the backside; after characterization, the solar cell will be tabbed and connected in series to other solar cells as part of the module fabrication process.

The tabs 120 can have many variations, such as: (1) portions 123 being 0.4 mm wide×0.8 mm tall; (2) portions 123 being 0.5 mm wide×0.6 mm tall; and (3) other variations—for example, the portions 123 can have highly reflective vertical surfaces to collect more light, as shown in FIG. 12, potentially overcoming the shadow losses incurred when light is incident at an angle. FIG. 12 shows a cross-sectional representation of a reflective tab 720 electrically connected to busbar 140 by a pre-tinned copper stud 750 with conductive adhesive material 751 between stud and busbar and stud and tab—the conductive adhesive may be a material such as conductive silver paste, solder, etc. Light rays 721 are incident on the reflective surface of the tab 720 and light rays 722 are the corresponding reflected rays which will be absorbed by the epitaxial silicon absorber layer. The handle and other layers are not shown for the sake of clarity. The light reflectivity of the sides of the tabs may be improved by coating with various metals if needed.

The solar cells with transparent handles as described herein may be formed into solar cell modules, wherein the solar cells are strung together in series—the tabs connecting the front of one solar cell to the back of the next—and the series connected solar cells are laminated between front and back sheets, is shown in FIGS. 1A & 1B. A method of fabricating a solar cell module according to some embodiments of the present invention may include: providing a plurality of silicon solar cells with transparent handles and integral tabs, as described herein; laminating the top surfaces of the transparent handles of the plurality of silicon solar cells to a front sheet; stringing together in series the plurality of silicon solar cells, the tabs of the plurality of silicon solar cells connecting the front of one solar cell to the back of the next in the series string; and laminating the back surfaces of the plurality of silicon solar cells to a back sheet. Further details of module fabrication are provided in U.S. patent application publication no. 2013/0056044 and PCT International Publication No. WO 2013/020111 to K. V. Ravi et al.

Advantages of the present invention may include: (1) enabling low shading losses on ultrathin epitaxial silicon without resorting to either MWT or IBC, for example an area gain of 2% or more is expected due solely to implementation of the low shading loss approaches of the present invention; (2) enabling the use of ultra-thin EVA (a significant cost reduction compared to the typical amount of EVA used in current modules—the EVA being thinner because in the present invention the EVA need only be the thickness of the busbar, whereas in the prior art the EVA needs to be the thickness of the tab) with a transparent handle for thin silicon solar cells; (3) reducing the amount of silver metal needed to form the busbars (another significant cost reduction), which are narrower than the typical 1.5 mm due to the use of narrower tabs; (4) fabrication cost can be low (well below $0.50/watt) with a reusable silicon substrate; and (5) an additional cost advantage comes from the use of low cost copper spheres and wires (for tabs) and less use of solder or conductive Ag pastes.

Using the low shading loss tabs, and pre-tinned studs of the present invention, thin silicon solar cells were fabricated—for example, as shown in FIG. 13. The fill factor for these thin silicon cells was measured in the range of 79 to 80 percent, which is a significant improvement over the more usual 75 to 76 percent fill factor for thin silicon measured for cells with conventional tabbing, and is comparable to the fill factors measured for conventional (thick) mono-silicon solar cells with conventional tabbing. Note that these thin silicon solar cells have epitaxial silicon layers with a total thickness of roughly 50 microns, and are representative of thin silicon solar cells having a thickness of the silicon epitaxial layers of about 120 microns or less. The reason for this improved fill factor using the process and structure of the present invention is believed to be due to lower stress in the epitaxial silicon layers than for the prior art structures. (In the prior art devices it is thought that the tabbed epitaxial layers are stressed—the thin epitaxial cells are tabbed before attaching the cells to the handle and since the tabs are typically 200 microns thick compared with the epitaxial layers, which are typically only 50 microns thick, and the tabs do not provide support unfirmly over the area of the epitaxial layers it is expected that the tabbed epitaxial layers are stressed. This is compared with the devices of the present invention which are attached to a handle, which provides uniform support to the epitaxial layers over their top surface, before tabbing.) Furthermore, the process and structure of the present invention are expected to result in improved yields over the prior art—the approach of the present invention is considered to be more robust.

Although the present invention has been described with reference to figures which show specific numbers of tabs, apertures, etc. these figures are representative of the structures and processes, and it is intended that the number of tabs, apertures, etc. will vary depending on the specific solar cells and modules, as will be clear to those of ordinary skill in the art. Furthermore, the figures, with the exception of FIG. 13, are not drawn to scale, but are provided in order to easily illustrate the structures and processes.

Although the present invention has been described with reference to thin silicon solar cells, the principles, teachings and examples of the present invention may also be applied to: thin, fragile and/or flexible solar cells; gallium arsenide based solar cells; solar cells such as described in U.S. patent application Ser. No. 13/776,471 entitled “Epitaxial Growth of III-V Solar Cells on Reusable Silicon Substrate with Porous Silicon Separation Layer”, incorporated in its entirety herein; conventional (thick) silicon solar cells; III-V and II-VI type material based solar cells; dual junction and triple junction solar cells including silicon; CIGS material based solar cells; etc. The tabs, transparent handles, and other features of the present invention may be used widely in the solar cell industry to replace the conventional tabs, etc.

Although the present invention has been particularly described with reference to certain embodiments thereof, it should be readily apparent to those of ordinary skill in the art that changes and modifications in the form and details may be made without departing from the spirit and scope of the invention.

What is claimed is:

1. A solar cell structure comprising:
solar cell layers with busbars on the surface of said solar cell layers;
a first layer of bonding material over the surface of said solar cell layers and over the surface of said busbars on said surface of said solar cell layers;
an optically transparent handle with grooves for tabs and apertures at the bottom of said grooves, wherein said grooves in said optically transparent handle are aligned with said busbars of said first structure and said apertures in said optically transparent handle are aligned with said openings in said first layer of bonding material, wherein said first layer of bonding material attaches said optically transparent handle to said solar cell layers, and wherein said first layer of bonding material has openings to match said apertures in said optically transparent handle;
electrical contact materials in said apertures in said optically transparent handle, said electrical contact materials making electrical contact between corresponding electrical contact materials and busbars; and
tabs in said grooves, said tabs making electrical contact between corresponding electrical contact materials and tabs.

2. The solar cell structure as in claim 1, wherein said tabs do not extend above the surface of said optically transparent handle.

3. The solar cell structure as in claim 1, wherein said solar cell layers are single crystal silicon layers.

4. The solar cell structure as in claim 1, further comprising a metal layer on the backside of said solar cell layers.

5. The solar cell structure as in claim 1, wherein said grooves have a height to width ratio of at least 1:1.

6. The solar cell as in claim 1, wherein said grooves have a height to width ratio of at least 2:1.

7. The solar cell as in claim 1, wherein said tabs have a first portion with a high aspect ratio for fitting in said groove of a first solar cell and a second portion having a low aspect ratio for making electrical contact to the back side of a second solar cell.

8. The solar cell as in claim 7, wherein said high aspect ratio is about 3.7:1.0.

9. The solar cell as in claim 7, wherein said low aspect ratio is about 1.0:7.5.

10. The solar cell structure as in claim 1, further comprising an optically transparent superstrate attached to said optically transparent handle by a second layer of bonding material.

11. A method of fabricating a solar cell comprising:
providing a structure including solar cell layers with busbars on the surface of said solar cell layers;
providing an optically transparent handle with grooves for tabs and apertures at the bottom of said grooves;
applying a sheet of bonding material over the surface of said solar cell layers and over the surface of said busbars on said surface of said solar cell layers, wherein said sheet has openings to match said apertures in said optically transparent handle;
aligning said grooves in said optically transparent handle with said busbars of said structure and said apertures in said optically transparent handle with said openings in said sheet, and laminating said optically transparent handle to said structure;
introducing electrical contact materials into said apertures in said optically transparent handle, and making electrical contact between corresponding electrical contact materials and busbars; and
inserting tabs into said grooves and making electrical contact between corresponding electrical contact materials and tabs.

12. The method as in claim 11, wherein said solar cell layers are epitaxial silicon layers on a silicon substrate.

13. The method as in claim 12, further comprising separating said epitaxial silicon layers attached to said transparent handle from said silicon substrate.

14. The method as in claim 13, further comprising, after said separating, depositing a metal layer on the backside of said epitaxial silicon layers.

15. The method as in claim 13, wherein said separating is after said inserting and said making electrical contact.

16. The method as in claim 13, wherein said separating is after said aligning and said laminating.

17. The method as in claim 11, further comprising after said inserting and said making electrical contact, laminating said optically transparent handle to an optically transparent superstrate.

18. The method as in claim 11, further comprising after said inserting and said making electrical contact, electrically connecting said solar cell in series with a second solar cell.

19. The method as in claim 11, further comprising after said inserting and said making electrical contact, electrically connecting said solar cell in series with a second solar cell and a third solar cell forming a series chain of solar cells.

20. The method as in claim 19, further comprising after said forming a series chain of solar cells, laminating said series chain of solar cells to an optically transparent superstrate.
